(19) United States
(12) Patent Application Publication
(10) Pub. No.: US 2013/0027527 A1
(43) Pub. Date: Jan. 31, 2013

(54) INSPECTION SYSTEM DEPLOYING PORTABLE HANDSET WITH ACTIVE COOLING FEATURE

(71) Applicants: Joshua Lynn Scott, Jordan, NY (US); Clark Alexander Bendall, Syracuse, NY (US); Theodore Alexander Chilek, Skaneateles, NY (US)

(72) Inventors: Joshua Lynn Scott, Jordan, NY (US); Clark Alexander Bendall, Syracuse, NY (US); Theodore Alexander Chilek, Skaneateles, NY (US)

(73) Assignee: General Electric Company, Schenectady, NY (US)

(21) Appl. No.: 13/190,672

(22) Filed: Jul. 26, 2011

(51) Int. Cl. H04N 7/18; H05K 7/20

(52) U.S. Cl. 348/61; 361/697; 348/E07.085

(57) ABSTRACT

Embodiments of an inspection system deploy active cooling to dissipate heat in a portable handset. In one embodiment, the inspection system comprise a visual inspection apparatus with a handle portion and a head portion coupled to the handle portion. The head portion can have a display and a circuit board coupled to the display and a heat sink in thermal connection with the circuit board. To facilitate active cooling, the apparatus may include an air moving device in flow connection with the heat sink, where the air moving device comprises a motor and an impeller and where the motor and the circuit board are sealed from the environment.

### BACKGROUND OF THE INVENTION

The subject matter disclosed herein relates to inspection systems and, more particularly, to embodiments of inspection systems, e.g., portable borescopes and videoscopes, that facilitate cooling and heat dissipation.

Commercially available inspection systems and devices are available in many forms including components distributed into a plurality of different housings. In one common form, components of the system include a hand held portion or “handset” and a spaced apart base unit each having a different associated housing. The handset may comprise various features including a visual display and corresponding circuitry to drive the display and to provide images that are collected by the inspection system. Moreover, to further improve the function of the system, the handset is often equipped to handle more complex data processing features that are useful for performing certain inspection tasks and image analysis.

These improvements generally increase the processing power that the handset must deploy, which, effectively, generates additional thermal energy in the form of, e.g., heat. To avoid disruption of function and possible damage to the handset, the handset must dissipate this heat away from critical components and out of the handset. Heat dissipation is often accomplished using passive cooling or, in other words, use of a heat sink to conduct heat to an area remote from the components and exposed to the surrounding environment. Unfortunately, in addition to the improved functionality, there is also a need to maintain and/or reduce the size and weight of the handset to enable portability and ease use for the end user. Passive cooling, however, often has the opposite effect because the heat sink must be enlarged to dissipate the increasing amount of heat that the improved handset generates.

The discussion above is merely provided for general background information and is not intended to be used as an aid in determining the scope of the claimed subject matter.

### BRIEF DESCRIPTION OF THE INVENTION

A inspection system is disclosed, wherein the inspection system has features and components that facilitate active cooling in the handset. An advantage that may be realized in the practice of some disclosed embodiments of the inspection system is to improve cooling and heat dissipation, while maintaining the portability and usability of the resulting device.

In one exemplary embodiment, a visual inspection apparatus is disclosed. The visual inspection apparatus comprises a handle portion and a head portion coupled to the handle portion. The head portion has a display and a circuit board coupled to the display. The visual apparatus also comprises a heat sink in thermal connection with the circuit board and an air moving device in flow connection with the heat sink, the air moving device comprising a motor and a impeller in driving engagement with the motor. In one example, the motor and the circuit board are sealed from the environment, and the heat sink is exposed so that air displaced by the impeller can flow across the heat sink and exhaust to the environment.

In another exemplary embodiment, an inspection system comprises a handset having a first compartment enclosing circuitry to drive a display and a heat sink configured to transfer heat from the first compartment to the environment. The inspection system also comprises an air moving device in flow connection with the heat sink. In one example, the first compartment and a portion of the air moving device are sealed from the environment and the heat sink is configured to permit air displaced by the air moving device to exhaust to the environment.

In another exemplary embodiment, a videoscope is disclosed. The videoscope comprises a handset comprising a display and a heat dissipating assembly comprising a heat sink and an air moving device in flow connection to the heat sink. The videoscope also comprises a probe member coupled to the handset, the probe member comprising a housing and an elongated tube extending from a first end proximate the housing to a second end at which light reflected from a target can enter the elongated tube and is directed back to the housing. In one example, the air moving device has a first portion that is sealed from the environment and a second portion that is configured to displace air across the heat sink.

This brief description of the invention is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

So that the manner in which the features of the invention can be understood, a detailed description of the invention may be had by reference to certain embodiments, some of which are illustrated in the accompanying drawings. It is to be noted, however, that the drawings illustrate only certain embodiments of this invention and are therefore not to be considered limiting of its scope, for the scope of the invention encompasses other equally effective embodiments. The drawings are not necessarily to scale, emphasis generally being placed upon illustrating the features of certain embodiments of invention. In the drawings, like numerals are used to indicate like parts throughout the various views. Thus, for further understanding of the invention, reference can be made to the following detailed description, read in connection with the drawings in which:

FIG. 1 is an a perspective, assembly view of an exemplary embodiment of an inspection system;

FIG. 2 is a perspective, exploded assembly view of the inspection system of FIG. 1;

FIG. 3 is a side, cross-section, exploded assembly view of the inspection system of FIGS. 1 and 2;

FIG. 4 is a perspective, exploded assembly view of an exemplary embodiment of an inspection system; and

FIG. 5 is a schematic wiring diagram of an exemplary embodiment of an inspection system.

### DETAILED DESCRIPTION OF THE INVENTION

As used herein, an element or function recited in the singular and proceeded with the word “a” or “an” should be understood as not excluding plural said elements or functions, unless such exclusion is explicitly recited. Furthermore, references to “one embodiment” of the claimed invention should not be interpreted as excluding the existence of additional embodiments that also incorporate the recited features.

Briefly, this disclosure describes inspection systems with a handset that deploys active cooling to accommodate functionality that generates excessive amounts of heat. Embodiments of such systems utilize a heat sink and an air moving device that causes air to flow over the heat sink. This combination facilitates the transfer of heat (and/or “thermal energy”) away from critical components and out of the handset to the environment. Moreover the configurations the inventors suggest below do not substantially increase the size and weight of the handset, thereby maintaining the overall mobility of the handset.

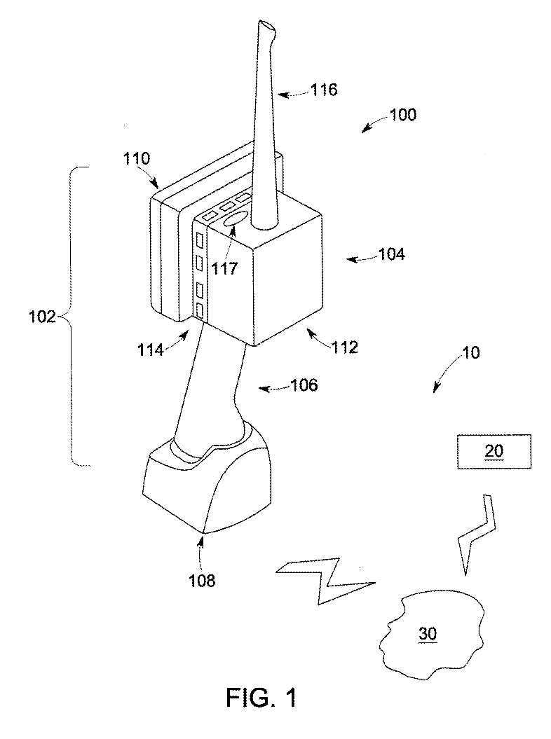

FIGS. 1, 2, and 3 illustrate in varying views an exemplary embodiment of an inspection system 100 that an end user can use for visual inspection in various applications, e.g., pipes and tubes, turbine engines, etc. In FIG. 1, the inspection system 100 includes a visual inspection apparatus 102 (or “handset 102”) with a head portion 104 and a handle portion 106. The inspection system 100 also includes a base member 108, which the handle portion 106 engages to, e.g., charge batteries (not shown) that power the handset 102.

On the head portion 104, the handset 102 includes a display member 110, a probe member 112, and a heat dissipating assembly 114. The probe member 112 has an elongated tube 116 that can direct light from the probe member 112 onto a target (not shown) and gather light that reflects from the target to distribute back to the probe member 112. The inspection system 100 can also comprise an air inlet, shown here as numeral 117 and disposed in the probe member 112. It is recognized, however, that the air inlet can be positioned in numerous other positions so as to provide cooling air into the heat dissipating assembly 114 as discussed further below. The inlet 117 preferably has features that permit air to permeate to the air to penetrate the heat dissipating assembly 114 but that do not permit debris, liquids, and other materials to contaminate the interior of the handset 102. The inspection system 100 may be part of a network system 10, which has in one example one or more external devices 20 (e.g., an external server) coupled via a network 30.

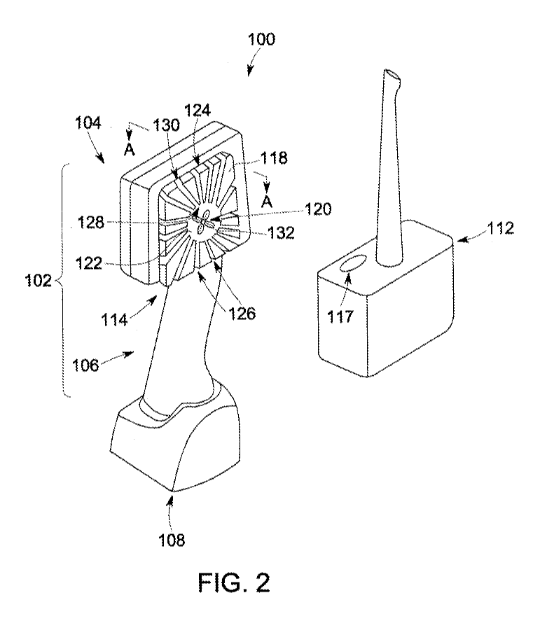

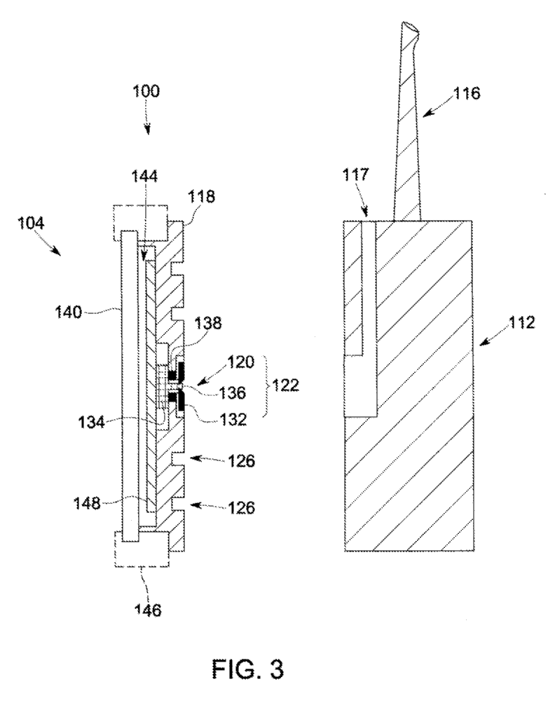

As best shown in FIGS. 2 and 3, the heat dissipating assembly 114 can comprise a heat sink 118 and an air moving device 120. The heat sink 118 has a central region 122, a peripheral edge 124, and a plurality of channels 126 with a first end 128 proximate the central region 122. The channels 126 also have a second end 130 that is open at the peripheral edge 124 to permit cooling air to exhaust from the heat sink 118 to the environment. The air moving device 120 can comprise an impeller 132 (e.g., fan blades) that cause air to flow over the heat sink 118 and, more typically, through one or more of the channels 126. Note that although the air moving device 120 and the central region 122 are located in the generally center or middle of the heat sink 118, the present disclosure contemplates other positions for the various parts of the heat dissipating assembly 114. In one example, the heat dissipating assembly 114 is configured proximate the source of the greatest amount of heat. This source may be centrally-located as shown and/or located in other locations that require the configuration of the heat dissipating assembly 114 to change as necessary.

FIG. 3 illustrates a cross-section of the head portion 104 along line A-A of FIG. 2 and in which other parts of the air moving device 120 are now visible. In addition to the impeller 132, the air moving device 120 also includes a motor 134 and a shaft 136 which transmits rotation from the motor 134 to the impeller 132. Because the shaft 136 extends through the heat sink 118 in this example, the head portion 104 includes an annular seal 138 that surrounds the shaft 136. The head portion 104 may also have a display device 140 and a first compartment 144, which can be sealed to the environment and/or otherwise impervious to liquids (e.g., “water-tight”). A housing 146 can form the exterior of the head portion 104.

A circuit board 148 and other electronic components (e.g., the motor 134) that are sensitive to, e.g., water, may reside in the first compartment 144. The circuit board 148 can comprise circuitry that drives the display device 140. Although not shown, the circuit board 148 can also comprise processor(s), memory(s), image sensor(s), and other ancillary devices and elements that facilitate functions on the handset 102. These functions include video image processing and display, which are common to, e.g., video borescopes and similar inspection tools.

The annular seal 138 permits rotation of the shaft 136, while sealing the interior of the first compartment 144 from the environment. In one example, this component seals the periphery of the shaft 136 to prevent liquid (e.g., water) from entering the first compartment 144 through any opening through which the shaft 136 extends. The annular seal 138 can comprise elastomeric elements (e.g., o-rings) that fit about the shaft to form the seal. In other examples, the annular seal 138 comprises one or more mechanical elements (e.g., bearings, bushings, etc.) which facilitate rotation and seal the first compartment 144.

The housing 146 can enclose and surround the periphery of the head portion 104. Typically comprising plastic or other moldable material, the housing 146 can have many forms which can be both aesthetically pleasing and functionally useful. For example, the housing 146 many enclose and surround the outer periphery of the display device 140 to secure the display device 140 in the head portion 104. Likewise the housing 146 can be secured to the heat sink 118, sometimes in surrounding relation to the heat sink 118 to form a unitary assembly for packaging these components together. In one embodiment, the housing 146 may provide sufficient sealing of the critical components forming, in one example, an outer peripheral part of the first compartment 144.

The heat sink 118 has a body that can comprise aluminum or other thermally-conductive material. The body can be formed monolithically or in any number of pieces that conform to the form factor of the head portion 104. Features such as the central region 122 and the channels 126 can be formed in the body using known techniques (e.g., machining, casting, molding, etc.). The central region 122 can have a generally circular shape, as shown in FIG. 2. This shape may conform to the size and configuration of the air moving device 120. For example, the circular shape has a diameter that permits the impeller 132 to rotate.

In one embodiment, the heat sink 118 has a surface that is exposed to the inside of the first compartment 144. This surface forms an interior wall of the first compartment 144. The exposed surface collects thermal energy and transfers the thermal energy, e.g., by conduction, through the body of the heat sink 118. The channels 126 can extend from the central region 122, wherein the first end 128 opens into the interior of the central region 122 to expose the channel 126 thereto. The channels 126 place the central region 122 in flow connection to the environment. As shown in this example, heated air can exit the heat sink 118 at the peripheral edge 124 via openings at the second end 130. The channels 126 increase the surface area through which heat can dissipates. The channels 126 can also direct cooling air that flows through the channels 126 from the central region 122 to the peripheral edge 124. The amount of available surface area may depend on the arrangement and/or pattern of the channels 126. In one example, the channels 126 are spaced radially about the opening through which the shaft 136 extends. The inventors contemplate other patterns including patterns in which the channels 126 extend lengthwise and/or widthwise across the body. In other examples, the resulting pattern for the channels 126 combines various arrangements including the radial, lengthwise, and widthwise patterns discussed above. In still other examples, the central region 122 is located in positions about the heat sink 118 such as closer to the peripheral edge 124.

Parts of the heat sink 118 may support portions of the display device 140 and the circuit board 146. These parts may be in the form of standoffs and/or bosses that extend from the exposed surface to receive components thereon. Fasteners can secure the components to the standoffs. As shown in FIG. 3, the motor 134 and the circuit board 148 fit within the first compartment 144 to protect these components from the environment. In one example the circuit board 146 is secured directly to the heat sink 118. This configuration effectively reduces any air gap between the circuit board 148 and the exposed surface of the heat sink 118, thereby promoting better transfer of heat from the circuit board 148 to the heat sink 118. The motor 134 may be secured directly to the exposed surface of the heat sink 118. In one example, the motor 134 can also be secured to the circuit board 148, e.g., using solder, solder paste, and/or other adhesive.

The heat sink 118 may also support the probe member 112. This configuration promotes heat dissipation from the probe member 112 using the same heat dissipating assembly 114. In one embodiment, the heat sink 118 comprise two separate pieces that, when secured to one another, form the channels 126 therein. One of the pieces is secured to the probe member 112 and one of the pieces is secured to the display member 110.

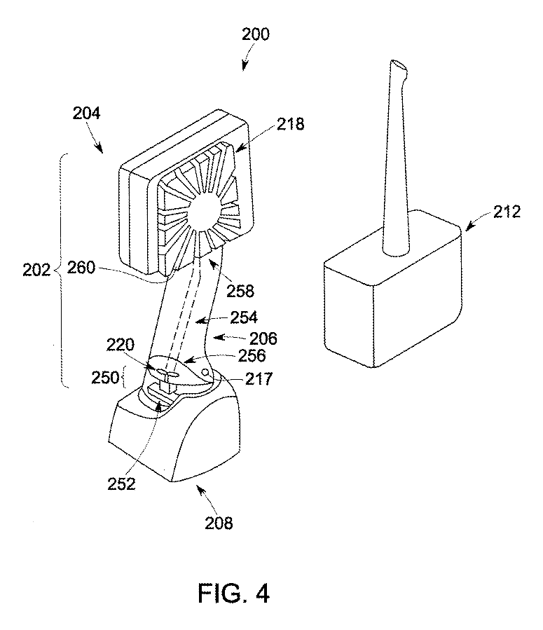

Referring next to FIG. 4, another exemplary embodiment of an inspection system 200 is illustrated. The inspection system 200 includes a visual inspection apparatus 202 (or “handset 202”) with a head portion 204, a handle portion 206, and a base member 208, and a probe member 212. The handset 202 also includes a heat sink 218, an air inlet 217, and an air moving device 220. For clarity, some features of the inspection system that are described above have been removed and/or are not shown in this example. However, the inventors note that the inspection system 200 may include the features and elements described in connection with other embodiments of inspection systems (e.g., the inspection system 100 of previous figures).

The handle portion 206 comprises a second compartment 250 in which a power source 252 and a portion (e.g. the motor) of the air moving device 220 are disposed. The handle portion 206 also comprises a duct 254 that has a first opening 256 proximate the second compartment 250. The duct 254 also has a second opening 258 proximate the head portion 204 and in communication with a cooling feature 260 incorporated into the heat sink 218.

In one embodiment, the air moving device 220 causes cooling air to circulate through the cooling feature 260. The cooling air flows through the handle portion 206 via the duct 254. The handle portion 206 and/or the duct 254 communicates the cooling air to the cooling feature 260, thus providing a mechanism to dissipate heat as described above. The cooling feature 260 is configured to distribute the cooling air about the heat sink 218. In one example, the cooling feature 260 comprises a network of channels (e.g., the channels 126 of previous figures) or fins or other features that can increase surface area and improve heat dissipation for transfer of thermal energy form parts of the head portion 204 to occur.

The handle portion 206 can be hollow, solid, or of such configuration as to provide sufficient strength to support the head portion 202. When hollow, the interior space of the handle portion 206 can act as the duct 254. In other example, the duct 254 may conform to a separate element, having an interior column that is separate from the interior volume of the handle portion 206. This interior column can place a portion (e.g., the impeller) of the air moving device 220 in flow connection with the cooling feature 260.

The second compartment 250 prevents exposure of the motor of the air moving device 220 to the environment. As discussed above, the second compartment 250 can incorporate a water-tight seal that prevents liquids from entering the second compartment 250. In one example, the air moving device 220 may include a shaft that extends through a wall or divider that creates the second compartment 250 in the handle portion 206. The shaft may require a seal or other element that preserves the integrity of the second compartment 250. In one example, the second compartment 250 comprises an access door (not shown) that permits the power source 252 to be removed. In another example, the second compartment 250 can be split into more than one compartment so that the power source 252 is effectively separated from the motor.

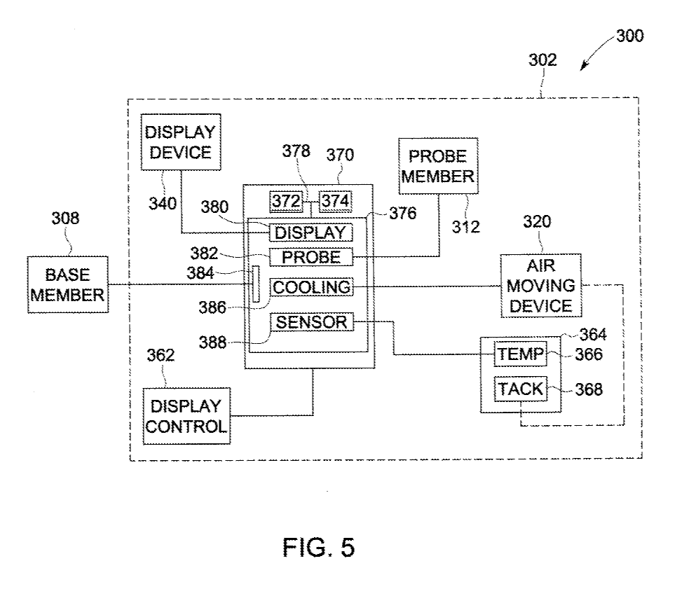

Turning now to FIG. 5, the disclosure now discusses various operational characteristics of embodiments of the inspection system contemplated herein. FIG. 5 illustrates an exemplary schematic wiring-diagram for an inspection system 300 (e.g., the inspection systems 100, 200 of previous figures). The inspection system 300 comprises a handset 302, a base member 308, a probe member 312, an air moving device 320, and a display device 340. The inspection system 300 may also comprise one or more display controls 362 and sensors 364 including a temperature sensor 366 and a tachometer 368, which is coupled to the air moving device 320. In the present example, the inspection system 300 also includes a control device 370 with a processor 372, a memory 374, and control circuitry 376, all coupled together by busses 378. The control circuitry 376 may comprise a display driver circuit 380, a probe driver circuit 382, a base interface circuit 384, a cooling control circuit 386, and a sensing circuit 388.

At a relatively high level, the control device 370 may include various components such as a processor, a memory, and control circuitry configured for general operation of the inspection systems discussed above. Collectively the parts of the control device 370 execute high-level logic functions, algorithms, as well as firmware and software instructions. In one example, the processor 372 is a central processing unit (CPU) such as an ASIC and/or an FPGA. The processor 372 can also include state machine circuitry or other suitable components capable of receiving inputs from the sensors 364. The memory 374 includes volatile and non-volatile memory and can be used for storage of software (or firmware) instructions and configuration settings. In some embodiments, the processor 372, the memory 374, and the control circuitry 376 can be contained in a single integrated circuit (IC) or other component. As another example, the processor can include internal program memory such as RAM and/or ROM. Similarly, any one or more of functions of these components can be distributed across additional components (e.g., multiple processors or other components).

The control device 370 is configured to operate the air moving device 320 in response to signals from the sensor 364. In one embodiment, the control device 368 can receive an input from the tachometer 368 that identifies an operating characteristics (e.g., rotational speed of motor) for the air moving device 320. To determine a change in the operating characteristic, the control device 370 can be configured to compare the operating characteristics to a threshold value. Deviations from the threshold value can prompt the control device 370 to change the operation of the air moving device 320 and/or to provide an alert (in the form of a visual indicator and/or audible tone). This feature is beneficial to identify when dirt/debris obstructs rotation of the motor, thereby reducing the speed of the motor that the tachometer 368 measures.

In another embodiment, the control device 370 may receive an input from the temperatures sensor 366. The input may reflect the temperature of a portion of the handset including the temperature of the heat sink, the temperature of the circuit board, and/or the temperature of the compartment in which the circuit board resides. Again the control device 370 can be configured to compare the temperature to the threshold value. In one example, if the temperature rises above the threshold value, then the control device 370 may generate an output that causes the air moving device 320 to activate and/or increase the speed of rotation. Likewise in another example, if the temperature falls is at and/or below the threshold value, then the control device 370 may generate an output that deactivate the air moving device 320 and/or decreases the speed of rotation.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A visual inspection apparatus, comprising:
a handle portion;
a head portion coupled to the handle portion, the head portion having a display;
a heat sink in thermal connection with the circuit board; and
an air moving device in flow connection with the heat sink, the air moving device comprising a motor and an impeller in driving engagement with the motor,
wherein the motor is sealed from the environment, and
wherein the heat sink is exposed so that air displaced by the impeller can flow across the heat sink and flow to the environment.

2. The visual inspection apparatus of claim 1, wherein the impeller is located proximate a center axis of the heat sink.

3. The visual inspection apparatus of claim 1, wherein the heat sink has a plurality of channels that are arranged radially about the impeller and extend from a first end proximate the impeller to a second end at an outer peripheral edge of the heat sink.

4. The visual inspection apparatus of claim 1, further comprising a shaft that extends through the heat sink and couples the motor and the impeller.

5. The visual inspection apparatus of claim 4, further comprising an annular seal disposed about the shaft, wherein the annular seal is configured to permit rotation of the shaft.

6. The visual inspection apparatus of claim 1, wherein the air moving device is disposed in the head portion.

7. The visual inspection apparatus of claim 1, wherein the air moving device is disposed in the handle portion.

8. The visual inspection apparatus of claim 1, wherein the circuit board is mounted to a surface of the heat sink.

9. The visual inspection apparatus of claim 1, wherein the circuit board is located between the display and the heat sink.

10. The visual inspection apparatus of claim 1, further comprising a cover element secured to the head portion and enclosing the heat sink therein, the cover element comprising an opening exposing the heat sink to the environment.

11. The visual inspection apparatus of claim 1, wherein the handle portion comprises a battery compartment.

12. An inspection system, comprising:
a handset having a first compartment enclosing circuitry to drive a display and a heat sink configured to transfer heat from the first compartment to the environment; and
an air moving device in flow connection with the heat sink,
wherein the first compartment and a portion of the air moving device are sealed from the environment, and
wherein the heat sink directs air displaced by the air moving device to flow to the environment.

13. The inspection system of claim 12, further comprising a controller coupled to the air moving device, wherein the controller is operatively configured to change operation of the air moving device in response to a first input respecting an operating parameter of the handset.

14. The inspection system of claim 13, wherein the operating parameter identifies the speed of a motor of the air moving device.

15. The inspection system apparatus of claim 13, wherein the operating parameter identifies a temperature of the handset.

16. A videoscope, comprising:
a handset comprising a display and a heat dissipating assembly comprising a heat sink and an air moving device in flow connection to the heat sink; and
a probe member coupled to the handset, the probe comprising a housing and an elongated member,
wherein the air moving device has a first portion that is sealed from the environment and a second portion that is configured to flow air across the heat sink.

17. The videoscope of claim 16, further comprising a base station, wherein the handset has a handle portion that is configured to engage the base station to charge batteries stored therein.

18. The videoscope of claim 17, wherein the first portion of the air moving device is disposed in the handle portion.

19. The videoscope of claim 16, wherein the heat sink is disposed between the handset and the housing of the probe member.

20. The videoscope of claim 19, wherein the heat sink comprises a plurality of channels with a first end proximate a central region of the heat sink, and wherein the channels are configured to direct air that enters the first end from the air moving device toward an outer peripheral edge of the heat sink.
